(19) United States
(12) Patent Application Publication
(10) Pub. No.: US 2011/0108104 A1
(43) Pub. Date: May 12, 2011

(54) PHOTOELECTRIC CONVERSION DEVICE

(75) Inventors: Hyun-Chul KIM, Suwon-si (KR); Ji-Won Lee, Suwon-si (KR); Joo-Sik Jung, Suwon-si (KR); Moon-Sung Kang, Suwon-si (KR); Su-Bin Song, Suwon-si (KR)

(73) Assignee: Samsung SDI Co., Ltd., Suwon-si (KR)

(21) Appl. No.: 12/749,829

(22) Filed: Mar. 30, 2010

(30) Foreign Application Priority Data
Nov. 9, 2009 (KR) 10-2009-0107513

(51) Int. Cl. H01L 31/00

(52) U.S. Cl. 136/256

(57) ABSTRACT

A photoelectric conversion device that includes: a light-receiving substrate, on which a photoelectrode is formed; a counter substrate that is disposed facing the light-receiving substrate, on which a counter electrode is formed; a semiconductor layer that is formed on the photoelectrode, into which a photosensitive dye is absorbed; and an electrolyte layer that is formed between the semiconductor layer and the counter electrode. The counter electrode includes a catalyst layer formed directly on the counter substrate.

### CROSS-REFERENCE TO RELATED APPLICATION

This application claims the benefit of Korean Patent Application No. 10-2009-0107513, filed on Nov. 9, 2009, in the Korean Intellectual Property Office, the disclosure of which is incorporated herein, by reference.

### BACKGROUND

1. Field

One or more embodiments of the present disclosure relate to a photoelectric conversion device.

2. Description of the Related Art

Recently, research has been conducted on various photoelectric conversion devices to convert light into electric energy, which can serve as a replacement for fossil fuels. In particular, solar batteries are attracting much attention.

From among the various types of solar batteries, wafer-type silicon or crystalline solar batteries using p-n semiconductor junctions are the most popular. However, these solar batteries are costly to manufacture, due to the use of high purity semiconductor materials.

Unlike a silicon solar battery, a dye-sensitized solar battery includes a photosensitive dye that reacts with light to generate electrons, a semiconductor material that receives the excited electrons from the dye, and an electrolyte that reacts with electrons returning from an external circuit. The dye-sensitized solar batteries have higher photoelectric conversion efficiencies than general solar batteries and thus, are regarded as the next-generation of solar batteries.

### SUMMARY

One or more embodiments of the present disclosure include a photoelectric conversion device having a high photoelectric conversion efficiency and a low manufacturing cost.

According to one or more embodiments of the present disclosure, a photoelectric conversion device includes: a light-receiving substrate, on which a photoelectrode is formed; a counter substrate disposed facing the light-receiving substrate, on which a counter electrode is formed; a semiconductor layer formed on the photoelectrode, into which a photosensitive dye is absorbed; and an electrolyte layer formed between the semiconductor layer and the counter electrode. The counter electrode includes a catalyst layer formed directly on the counter substrate.

According to various embodiments, a transparent conductive oxide (TCO) layer is not formed between the counter substrate and the catalyst layer.

According to various embodiments, the counter electrode may include grid electrodes formed on the catalyst layer. The grid electrodes may have a width equal to or less than about 0.1 mm. The distance between the grid electrodes may be equal to or less than about 2 mm. In particular, the distance between the grid electrodes may be equal to or less than about 1 mm.

According to various embodiments, the grid electrodes may include bus bars that extend in parallel, in a striped pattern; and a connection bar that extends across ends of the bus bars and gathers electrons generated due to photoelectric conversion, so as to send the electrons outside the photoelectric conversion device.

According to various embodiments, the grid electrodes may include: main bus bars that extend in a striped pattern along one direction; sub-bus bars that extend in another direction between the main bus bars, so as to connect the main bus bars to each other; and a connection bar that extends across ends of the main bus bars and gathers electrons generated due to photoelectric conversion, so as to send the electrons outside the photoelectric conversion device.

According to various embodiments, the grid electrodes may further include protruding bus bars that protrude from the main bus bars, into windows formed by the main bus bars and the sub-bus bars.

According to various embodiments, the catalyst layer may be formed as a thick film, by performing a sputtering process for more than about 600 sec.

According to various embodiments, the photoelectrode may include: a transparent conductive film formed on the light-receiving substrate; and grid electrodes formed on the transparent conductive film.

According to one or more embodiments of the present disclosure, a photoelectric conversion device includes: a light-receiving substrate, on which a photoelectrode is formed; a counter substrate that is disposed facing the light-receiving substrate, on which a counter electrode is formed; a semiconductor layer that is formed on the photoelectrode, into which a photosensitive dye is absorbed; and an electrolyte layer that is formed between the semiconductor layer and the counter electrode. The counter electrode includes a thin metal layer directly formed on the counter substrate and a catalyst layer formed on the thin metal layer.

According to various embodiments, a transparent conductive oxide (TCO) layer is not formed between the counter substrate and the catalyst layer.

According to various embodiments, the counter electrode may further include grid electrodes formed on the catalyst layer. The grid electrodes may be formed to have a width equal to or less than 0.1 mm. The distance between the grid electrodes may be equal to or less than 2 mm. In particular, the distance between the grid electrodes may be equal to or less than 1 mm.

According to various embodiments, the grid electrodes may include: bus bars that extend in parallel, in a striped pattern; and a connection bar that extends across ends of the bus bars, and gathers electrons generated due to photoelectric conversion, so as to send the electrons outside the photoelectric conversion device.

According to various embodiments, the grid electrodes may include: main bus bars that extend in a striped pattern, along one direction; sub-bus bars that extend in another direction, between the main bus bars, so as to connect the main bus bars to each other; and a connection bar that extends across ends of the main bus bars, and gathers electrons generated due to photoelectric conversion, so as to send the electrons outside the photoelectric conversion device.

According to various embodiments, the grid electrodes may include protruding bus bars that protrude from the main bus bars, into windows formed by the main bus bars and the sub-bus bars.

According to various embodiments, the catalyst layer may be formed as a thick film, by performing a sputtering process for more than about 600 sec.

According to various embodiments, the photoelectrode may include: a transparent conductive film formed on the light-receiving substrate; and grid electrodes formed on the transparent conductive film.

Additional aspects and/or advantages of the disclosure will be set forth in part in the description which follows and, in part, will be obvious from the description, or may be learned by practice of the disclosure.

### BRIEF DESCRIPTION OF THE DRAWINGS

These and/or other aspects and advantages of the present disclosure will become apparent and more readily appreciated from the following description of the exemplary embodiments, taken in conjunction with the accompanying drawings, of which:

FIG. 1 is a cross-sectional view of a photoelectric conversion device, according to an exemplary embodiment of the present disclosure;

FIG. 2 is a schematic diagram showing an exemplary pattern of grid electrodes illustrated in FIG. 1, according to an exemplary embodiment of the present disclosure;

FIG. 3 is detailed cross-sectional view of a counter substrate side illustrated in FIG. 1, according to an exemplary embodiment of the present disclosure;

FIG. 4 is a graph showing variations in short circuit current density and filling factor based on a coating time of a catalyst layer illustrated in FIG. 3, according to an exemplary embodiment of the present disclosure;

FIGS. 5 through 7 are schematic diagrams showing modified patterns of grid electrodes illustrated in FIG. 2, according to exemplary embodiments of the present disclosure;

FIGS. 8A through 8D are cross-sectional views for describing a method of forming a counter electrode illustrated in FIG. 3, according to an exemplary embodiment of the present disclosure;

FIG. 9 is a cross-sectional view of a photoelectric conversion device, according to another exemplary embodiment of the present disclosure;

FIG. 10 is detailed cross-sectional view of a counter substrate side illustrated in FIG. 9, according to an exemplary embodiment of the present disclosure;

FIG. 11 is a cross-sectional view of a photoelectric conversion device, according to another exemplary embodiment of the present disclosure; and

FIG. 12 is detailed cross-sectional view of a counter substrate side illustrated in FIG. 11, according to an exemplary embodiment of the present disclosure.

### DETAILED DESCRIPTION

Reference will now be made in detail to the exemplary embodiments of the present disclosure, examples of which are illustrated in the accompanying drawings, wherein like reference numerals refer to the like elements throughout. In this regard, the present exemplary embodiments should not be construed as being limited to the descriptions set forth herein. Accordingly, the exemplary embodiments are merely described below, by referring to the figures, in order to explain aspects of the present description.

Herein, when a first element is referred to as being formed or disposed “on” a second element, the first element can be disposed directly on the second element, or one or more other elements may be disposed therebetween. When a first element is referred to as being formed or disposed “directly on” a second element, no other elements are disposed therebetween.

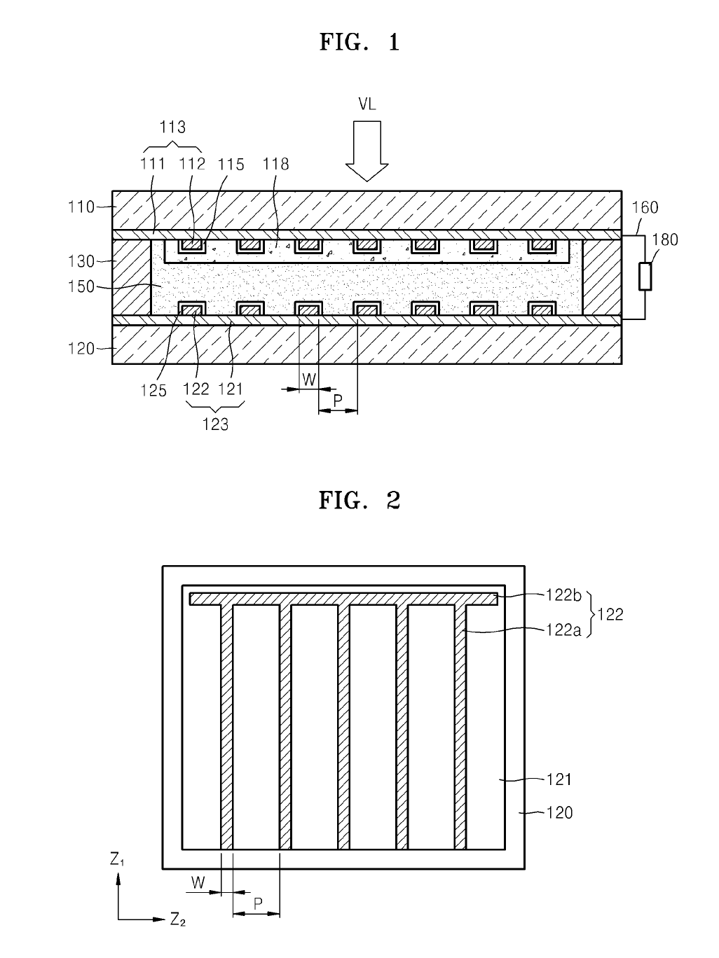

FIG. 1 is a cross-sectional view of a photoelectric conversion device, according to an exemplary embodiment of the present disclosure. Referring to FIG. 1, the device includes: a light-receiving substrate 110; a photoelectrode 113 formed on the substrate 110; a counter substrate 120 facing the substrate 110; a counter electrode 123 formed on the substrate 120; a semiconductor layer 118 formed on the photoelectrode 113, into which a photosensitive dye is absorbed; and an electrolyte layer 150 formed between the semiconductor layer 118 and the counter electrode 123.

The light-receiving substrate 110 and the counter substrate 120 are bonded together using a sealant 130, such that a gap is formed therebetween. An electrolyte may be filled in the gap between the light-receiving substrate 110 and the counter substrate 120, to form the electrolyte layer 150. The photoelectrode 113 and the counter electrode 123 are electrically connected by wires 160 to an external circuit 180. However, when a plurality of photoelectric conversion devices are connected in series or parallel, so as to form a module, photoelectrodes 113 and counter electrodes 123 of the photoelectric conversion devices may be connected in series or parallel. Opposing ends of the connected photoelectric conversion devices may be connected to the external circuit 180.

The light-receiving substrate 110 may be formed of a transparent material having a high light transmittance. For example, the light-receiving substrate 110 may be a glass substrate or a resin film. A resin film is generally flexible and may be used when flexibility is required. The counter substrate 120 does not particularly require transparency, but may be formed of a transparent material, such that visible light VL may be transmitted through both sides of the photoelectric conversion device, in order to increase photoelectric conversion efficiency thereof. The counter substrate 120 may be formed of the same material as the light-receiving substrate 110. In particular, when the photoelectric conversion device is used in, for example, a window frame as a building integrated photovoltaic (BIPV), both sides of the photoelectric conversion device may have transparency so as not to block the light VL that may enter from the outside.

The photoelectrode 113 may include a transparent conductive film 111 and grid electrodes 112 formed in a mesh pattern on the transparent conductive film 111. The transparent conductive film 111 is formed of a material that is electrically conductive, for example, indium-doped tin oxide (ITO), fluorine-doped tin oxide (FTO), or antimony-doped tin oxide (ATO). The grid electrodes 112 electrically contact the transparent conductive film 111 and supplement a relatively low electrical conductivity of the transparent conductive film 111. For example, the grid electrodes 112 may be formed of a metallic material having an excellent electrical conductivity, such as gold (Au), silver (Ag) or aluminum (Al), and may be patterned in a mesh shape.

The photoelectrode 113 operates as a negative electrode of the photoelectric conversion device and may have a high aperture ratio. The light VL that enters through the photoelectrode 113 excites the photosensitive dye absorbed into the semiconductor layer 118. Thus, the photoelectric conversion efficiency may be enhanced by allowing as much of the light VL to enter as possible. For example, an aperture ratio represents a ratio of an incidence area, through which the light VL may enter to a substrate area, on which the photoelectrode 113 is formed. Since the grid electrodes 112 are formed of an opaque material, such as a metallic material, in most cases, an area on which the grid electrodes 112 are formed, that is, the width of the grid electrodes 112, reduces the incidence area through which the light VL may enter. Thus, decreasing the aperture ratio decreases the amount of light received. Considering the aperture ratio, the grid electrodes 112 may be formed having a small width. However, since the grid electrodes 112 are used to decrease the electric resistance of the photoelectrode 113, the distance between neighboring grid electrodes 112 may be small, so as to offset the increase in resistance that may occur by restricting the width of the grid electrodes 112.

A protective layer 115 may be further formed on outer surfaces of the grid electrodes 112. The protective layer 115 prevents the grid electrodes 112 from being damaged, for example, prevents the grid electrodes 112 from being corroded by the electrolyte layer 150. The protective layer 115 may be formed of a material that does not react with the electrolyte layer 150, for example, a curable resin material.

The semiconductor layer 118 may be formed of a semiconductor material used in a general photoelectric conversion device, for example, an oxide of a metal such as cadmium (Cd), zinc (Zn), indium (In), lead (Pb), molybdenum (Mo), tungsten (W), antimony (Sb), titanium (Ti), silver (Ag), manganese (Mn), tin (Sn), zirconium (Zr), strontium (Sr), gallium (Ga), silicon (Si) or chromium (Cr). The semiconductor layer 118 may increase photoelectric conversion efficiency by absorbing the photosensitive dye. For example, the semiconductor layer 118 may be formed by coating a paste, in which semiconductor particles having diameters from about 5 nm to about 1000 nm are distributed, on the light-receiving substrate 110, on which the photoelectrode 113 is formed, and then performing a heating or pressing process.

The photosensitive dye absorbed into the semiconductor layer 118 absorbs the light VL that is transmitted through the light-receiving substrate 110, and electrons in the photosensitive dye are excited from a ground state to an excited state. The excited electrons are transferred to a conduction band of the semiconductor layer 118, due to an electrical connection between the photosensitive dye and the semiconductor layer 118. The electrons then pass through the semiconductor layer 118 to reach the photoelectrode 113, and exit the photoelectric conversion device, through the photoelectrode 113, thereby forming a driving current used to drive the external circuit 180.

For example, the photosensitive dye absorbed into the semiconductor layer 118 is formed of molecules that may absorb visible light and enter an excited state. The excited electrons are then collected by the semiconductor layer 118. The photosensitive dye may be in the form of a liquid, a gel, or a solid. For example, the photosensitive dye may be a ruthenium (Ru)-based photosensitive dye. The photosensitive dye may be absorbed into the semiconductor layer 118, by dipping the light-receiving substrate 110, on which the semiconductor layer 118 is formed, in a solution containing the photosensitive dye.

The electrolyte layer 150 may be formed of a redox electrolyte containing reduced/oxidized couples. The electrolyte may be in the form of a solid, a gel or a liquid.

The counter electrode 123 includes a catalyst layer 121 and grid electrodes 122 formed in a mesh pattern on the catalyst layer 121. The catalyst layer 121 is a reduction catalyst that provides electrons to the electrolyte layer 150. The catalyst layer 121 may be formed of, for example, a metal such as platinum (Pt), gold (Au), silver (Ag), copper (Cu), or aluminum (Al), a metal oxide such as Sn oxide, or a carbon (C)-based material such as graphite.

The grid electrodes 122 are formed directly on and electrically contact the catalyst layer 121. The grid electrodes 122 may supplement the conductivity of the catalyst layer 121, and may decrease the resistance of the counter electrode 123. The grid electrodes 122 may be formed of the same material as the grid electrodes 112, which face the grid electrodes 122. For example, the grid electrodes 122 may be formed of a metallic material having an excellent electrical conductivity, such as Gold (Au), silver (Ag), or aluminum (Al). The grid electrodes 122 may be formed in a matrix.

A protective layer 125 may be further formed on outer surfaces of the grid electrodes 122. The protective layer 125 prevents the grid electrodes 122 from being damaged, for example, prevents the grid electrodes 122 from corroding due to contact and reaction with the electrolyte layer 150. The protective layer 125 may be formed of a material that does not react with the electrolyte layer 150, for example, a curable resin material.

FIG. 2 is a schematic diagram showing an exemplary pattern of the grid electrodes 122 illustrated in FIG. 1, according to an embodiment of the present disclosure. Referring to FIG. 2, the grid electrodes 122 may include bus bars 122a that extend in parallel, in a striped pattern, along a first direction Z1, and a connection bar 122b that extends in a second direction Z2 across the bus bars 122a. The connection bar 122b gathers electrons generated due to photoelectric conversion, so as to send the electrons outside of the photoelectric conversion device. Meanwhile, reference numerals P and W respectively represent a distance between, and a width of, the bus bars 122a.

Referring to FIG. 1, the counter electrode 123 operates as a positive electrode and as a reduction catalyst to provide electrons to the electrolyte layer 150. The photosensitive dye absorbed into the semiconductor layer 118 absorbs the light VL, which excites the electrons in the photosensitive dye. The excited electrons are collected by the photoelectrode 113. After losing electrons, the photosensitive dye is reduced by receiving electrons provided by the oxidation of the electrolyte layer 150. The oxidized electrolyte layer 150 is in turn reduced by electrons that reach the counter electrode 123, through the external circuit 180, thereby completing operations of the photoelectric conversion device.

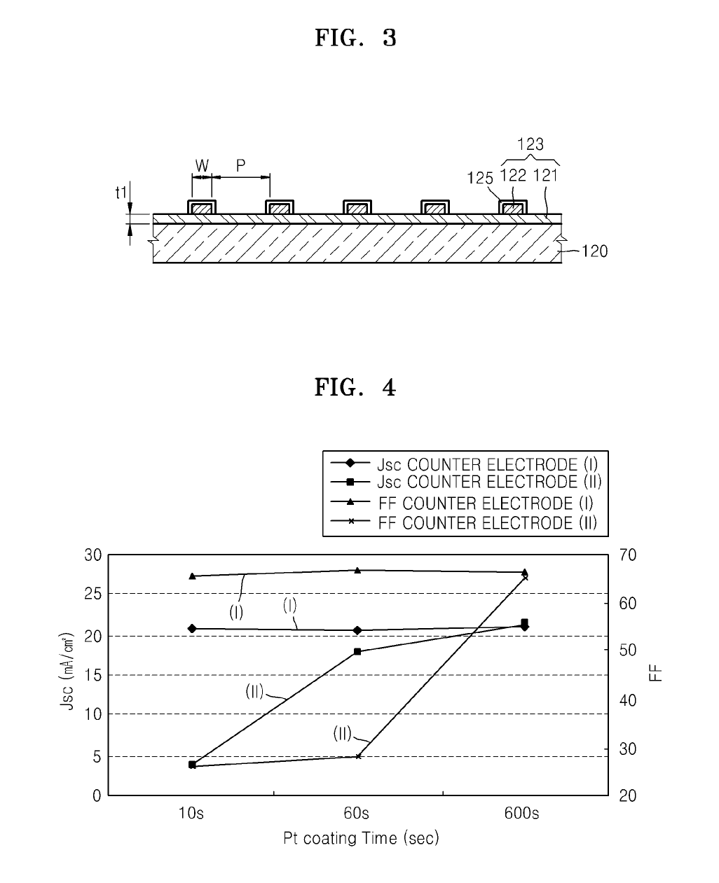

FIG. 3 is detailed cross-sectional view of a counter substrate side illustrated in FIG. 1, according to an embodiment of the present disclosure. Referring to FIG. 3, the catalyst layer 121 is directly formed on one surface of the counter substrate 120, without any other layer being formed therebetween. In particular, a transparent conductive oxide (TCO) layer is not included between the counter electrode 123 and the counter substrate 120. A TCO layer causes an increase in manufacturing cost of a device, due to high material costs and expensive unique film-forming processes. Since a TCO layer is not formed, manufacturing costs of the photoelectric conversion device may be greatly decreased.

FIG. 4 is a graph showing variations in short circuit current density Jsc and filling factor FF, based on a coating time of the catalyst layer 121 illustrated in FIG. 3, according to an embodiment of the present disclosure. The short circuit current density Jsc and the filling factor FF are directly linked with photoelectric conversion efficiency η. In more detail, the photoelectric conversion efficiency η may be represented as shown in Equation 1.

η=100×(Voc×Jsc×FF)/Po [Equation 1]

In Equation 1, Voc represents an open circuit voltage (V), Jsc represents a short circuit current density (mA/cm2), FF represents a filling factor, and Po represents the intensity of incidence light (mW/cm²).

In FIG. 4, a counter electrode I is formed by forming a TCO layer on a counter substrate 120 and forming the catalyst layer 121 on the TCO layer. A counter electrode II is formed by directly forming the catalyst layer 121 on the counter substrate 120, as illustrated in FIG. 3. The counter electrodes I and II differ only by the inclusion of the TCO layer. In this case, the catalyst layer 121 is formed using a Pt material and a sputtering process, and an increase in the coating time results in an increase in a thickness t1 of the catalyst layer 121.

The counter electrodes I and II having a short coating time of about 10 seconds have a large difference in performance with respect to the short circuit current density Jsc and the filling factor FF. As the coating time of the catalyst layer 121 increases, the short circuit current density Jsc and the filling factor FF of the counter electrode II are greatly improved, and electrical properties of the counter electrodes I and II become similar. As the thickness t1 of the catalyst layer 121 increases, electric properties of the counter electrode II greatly vary and are similar to those of the counter electrode I with respect to the short circuit current density Jsc and the filling factor FF, when the coating time exceeds about 600 sec. As a result, if the thickness t1 of the catalyst layer 121 is greater than a certain level, the counter electrode 123 not including a TCO layer may also have electrical properties equivalent to those of a counter electrode including a TCO layer.

In addition to the thickness t1 of the catalyst layer 121, the electrical properties of the counter electrode 123 may also vary, based on a design of the grid electrodes 122. Table 1 shows variations in electrical properties of the counter electrode 123, based on a design of the grid electrodes 122.

TABLE 1

| | Distance | | | | Valid | | Internal |
|---|---|---|---|---|---|---|---|
| Substrate | between | Width of | | Electrode | Incidence | Valid Area | Equivalent |
| Area | Electrodes | Electrodes | No. of | Area | Area | Ratio | Resistance |
| (cm²) | (nm) | (mm) | Electrodes | (cm²) | (cm²) | (%) | (Ω) |
| 100 | 5 | 0.1 | 19.61 | 1.96 | 98.04 | 98.04 | 111.2839 |
| 100 | 5 | 005 | 19.80 | 0.99 | 99.01 | 99.01 | 113.3249 |
| 100 | 4 | 0.1 | 24.39 | 2.44 | 97.56 | 97.56 | 102.0184 |
| 100 | 4 | 0.05 | 24.69 | 1.23 | 98.77 | 98.77 | 104.0641 |
| 100 | 3 | 0.1 | 32.26 | 3.23 | 96.77 | 96.77 | 86.7193 |
| 100 | 3 | 0.05 | 32.79 | 1.64 | 98.36 | 98.36 | 88.7666 |
| 100 | 2 | 0.1 | 47.62 | 4.76 | 95.24 | 95.24 | 68.6864 |
| 100 | 2 | 0.05 | 48.78 | 2.44 | 97.56 | 97.56 | 70.7360 |
| 100 | 1 | 0.1 | 90.91 | 9.09 | 90.91 | 90.91 | 35.9686 |
| 100 | 1 | 0.05 | 95.24 | 4.76 | 95.24 | 95.24 | 38.0472 |
| 100 | 0.5 | 0.1 | 166.67 | 16.67 | 83.33 | 83.33 | 19.2224 |
| 100 | 0.5 | 0.05 | 181.82 | 9.09 | 90.91 | 90.91 | 21.1926 |

Values of Table 1 are obtained with respect to the counter electrode 123, which does not include a TCO layer and includes the catalyst layer 121 having a coating time of 10 sec. Variations in internal equivalent resistance are measured, while the width W and the distance P between the grid electrodes 122 are varied as design variables. In more detail, while a substrate area on which the counter electrode 123 is formed is maintained to be 100 cm² and the distance P between the grid electrodes 122 is varied from 0.5 mm to 5 mm, the internal equivalent resistance is measured with respect to two values of the width W, i.e., 0.1 mm and 0.05 mm, for each value of the distance P.

Since internal equivalent resistances greater than about 1000 are measured, with respect to values of the distance P greater than 4 mm, a photocurrent is restricted, and power generation efficiency of the photoelectric conversion device is reduced. Also, relatively high internal equivalent resistances greater than about 86Ω are measured, with respect to the values of the distance P that are greater than 3 mm, which is not appropriate. If the values of the distance P are set equal to or less than 2 mm, the internal equivalent resistance may be decreased to less than about 70Ω. Also, since the internal equivalent resistance is greatly reduced at when distance P is around 1 mm, distance P may be equal to or less than about 1 mm.

Since the grid electrodes 122 are formed of an opaque material, such as a metallic material, an incidence area, obtained by excluding an electrode area from an entire substrate area, is a valid incidence area through which the light VL may enter. In order to increase photoelectric conversion efficiency, the light VL may also enter through the counter substrate 120. Also, when the photoelectric conversion device is used in, for example, a window frame as a BIPV, the counter substrate 120 may also have transparency, so as not to block the light VL that may enter from the outside.

Accordingly, the grid electrodes 122 may be designed in consideration of the valid incidence area as well as the internal equivalent resistance. In Table 1, a valid area ratio that represents a ratio of a valid incidence area to an entire substrate area in the counter electrode 123 is greater than about 90%. Thus, an appropriate valid incidence area may be ensured.

FIGS. 5 through 7 are schematic diagrams showing modified patterns of the grid electrodes 122 illustrated in FIG. 2, according to exemplary embodiments of the present disclosure. Referring to FIG. 5, grid electrodes 222 include main bus bars 222a that extend in a first direction Z1 and sub-bus bars 222c that extend in a second direction Z2, between the main bus bars 222a, so as to connect the main bus bars 222a to each other. The main bus bars 222a are uniformly spaced apart by a first distance P1 and have a relatively large width W1. The sub-bus bars 222c are densely arranged, by being spaced apart by a second distance P2 that is smaller than the first distance P1. The sub-bus bars 222c have a relatively small width W2. The sub-bus bars 222c are used to decrease the electric resistance of a counter electrode.

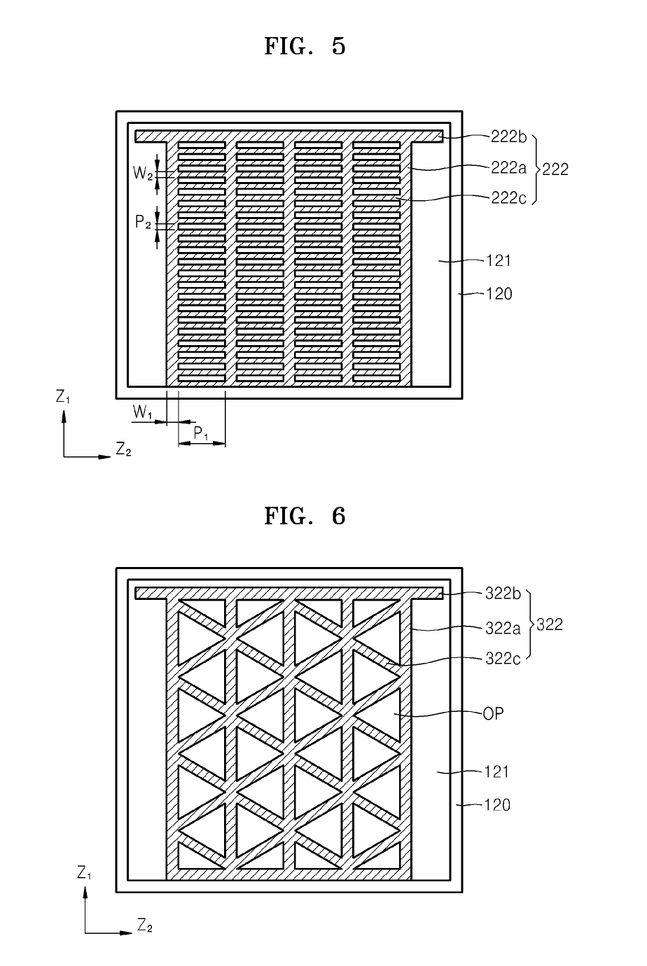

Referring to FIG. 6, grid electrodes 322 include main bus bars 322a that extend in a first direction Z1 and sub-bus bars 322c that extend in a zigzag pattern between the main bus bars 322a. The grid electrodes 322 form almost triangular windows OP and provide a current path having a low resistance.

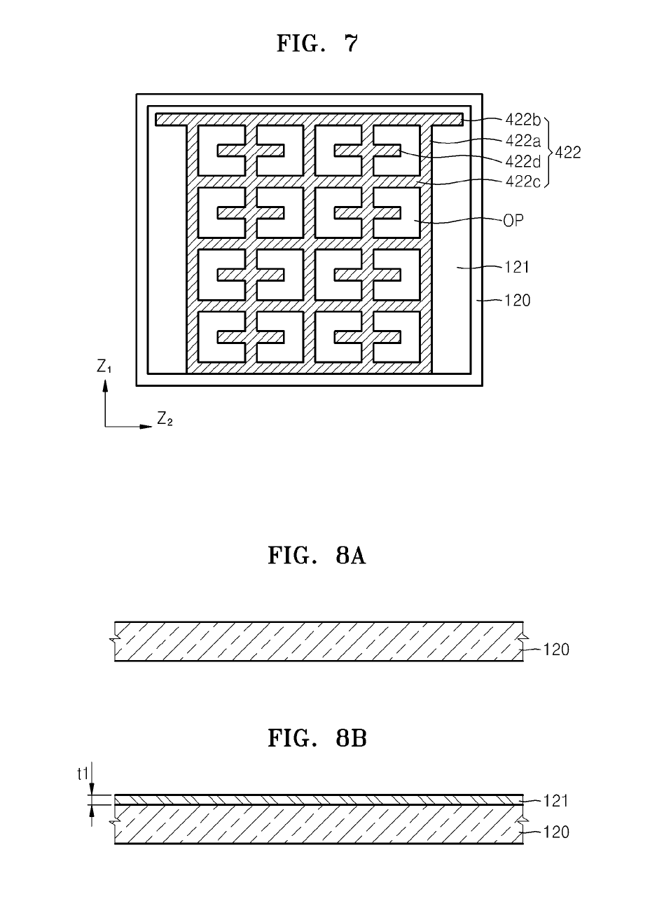

Referring to FIG. 7, grid electrodes 422 include main bus bars 422a that extend in a first direction Z1 and sub-bus bars 422c that extend in a second direction Z2, between the main bus bars 422a, so as to connect the main bus bars 422a to each other. The grid electrodes 422 form almost rectangular windows OP. The grid electrodes 422 may include protruding bus bars 422d that protrude from the main bus bars 422a into the windows OP.

In FIGS. 5 through 7, reference numerals 222b, 322b, and 422b respectively represent connection bars that extend in the second direction Z2, across the main bus bars 222a, 322a, and 422a, to the outside of a photoelectric conversion device. The patterns illustrated in FIGS. 5 through 7 may also be applied to the grid electrodes 112 of the photoelectrode 113 illustrated in FIG. 1. The grid electrodes 112 of the photoelectrode 113 may be formed in an appropriate pattern, in consideration of an aperture ratio and electric resistance properties.

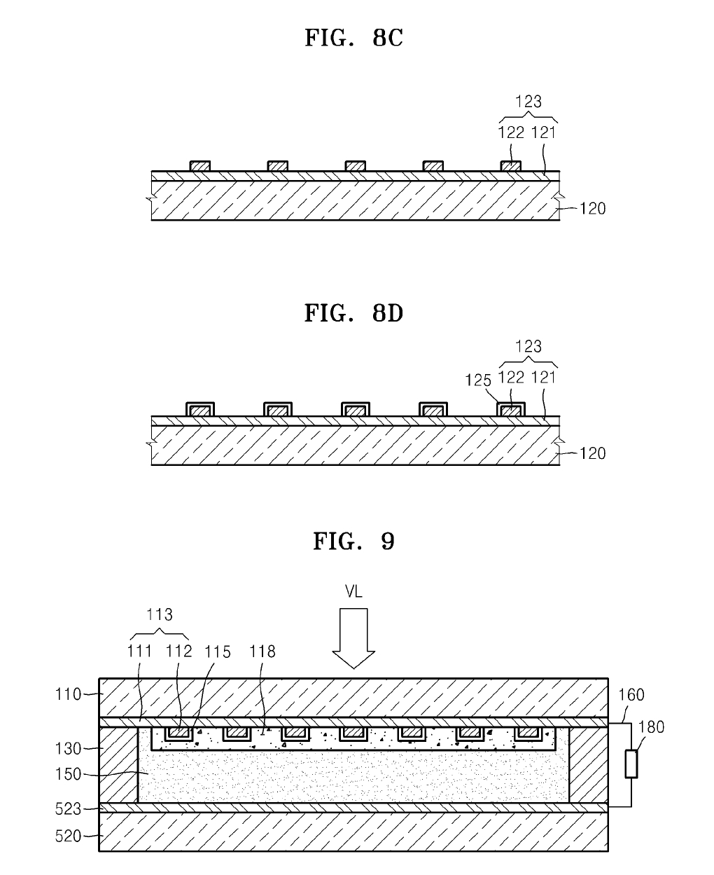

FIGS. 8A through 8D are cross-sectional views for describing a method of forming the counter electrode 123 illustrated in FIG. 3, according to an embodiment of the present disclosure. Referring to FIG. 8A, initially, the counter substrate 120 is prepared. The counter substrate 120 may be formed of a transparent material and may be, for example, a glass substrate or a resin film.

Referring to FIG. 8B, then, the catalyst layer 121 is formed on the counter substrate 120. The catalyst layer 121 may be formed of a material that operates as a reduction catalyst, through an appropriate film-forming process. For example, the catalyst layer 121 may be formed by sputtering a material such as Pt, Ag, Au, Cu, or Al. The thickness t1 of the catalyst layer 121 may be controlled by controlling a process time. In order to decrease the electric resistance of the counter electrode 121, the sputtering process may be performed for more than about 600 sec., so as to form the catalyst layer 121 as a thick film.

Referring to FIG. 8C, then, the grid electrodes 122 are formed on the catalyst layer 121, so as to form the counter electrode 123. For example, when the grid electrodes 122 are formed, a screen (not shown) having an aperture pattern corresponding to a pattern of the grid electrodes 122 may be used. A mesh pattern of the grid electrodes 122 may be obtained by putting an electrode material on the screen disposed over the catalyst layer 121 and pressing the electrode material in one direction using a squeezer (now shown). Then the electrode material pressed onto the catalyst layer 121 may be fixed, by performing a thermal process.

Referring to FIG. 8D, the protective layer 125 may optionally be formed on the outer surfaces of the grid electrodes 122. The protective layer 125 may be formed of a curable resin material that does not react with the electrolyte layer 150.

FIG. 9 is a cross-sectional view of a photoelectric conversion device, according to another exemplary embodiment of the present disclosure. FIG. 10 is detailed cross-sectional view of a counter substrate side illustrated in FIG. 9.

Referring to FIGS. 9 and 10, a light-receiving substrate 110 on which a photoelectrode 113 is formed, a semiconductor layer 118 into which a photosensitive dye is absorbed, an electrolyte layer 150, and a counter substrate 520 on which a counter electrode 523 is formed are sequentially stacked together. The photoelectrode 113 includes a transparent conductive film 111 and grid electrodes 112 formed in a mesh pattern on the transparent conductive film 111.

The counter electrode 523, which faces the photoelectrode 113, is a catalyst layer directly formed on the counter substrate 520. In FIGS. 9 and 10, the counter electrode 523 includes only a catalyst layer and thus, is different from the counter electrode 123 illustrated in FIGS. 1 and 3, which includes the catalyst layer 121 and the grid electrodes 122 formed on the catalyst layer 121. The counter electrode 523 may be formed by performing an appropriate film-forming process, such as a sputtering process. A thickness t2 of the counter electrode 523 may be controlled by controlling processing time. In order to supplement electric properties of the counter electrode 523, the counter electrode 523 may be formed as a thick film.

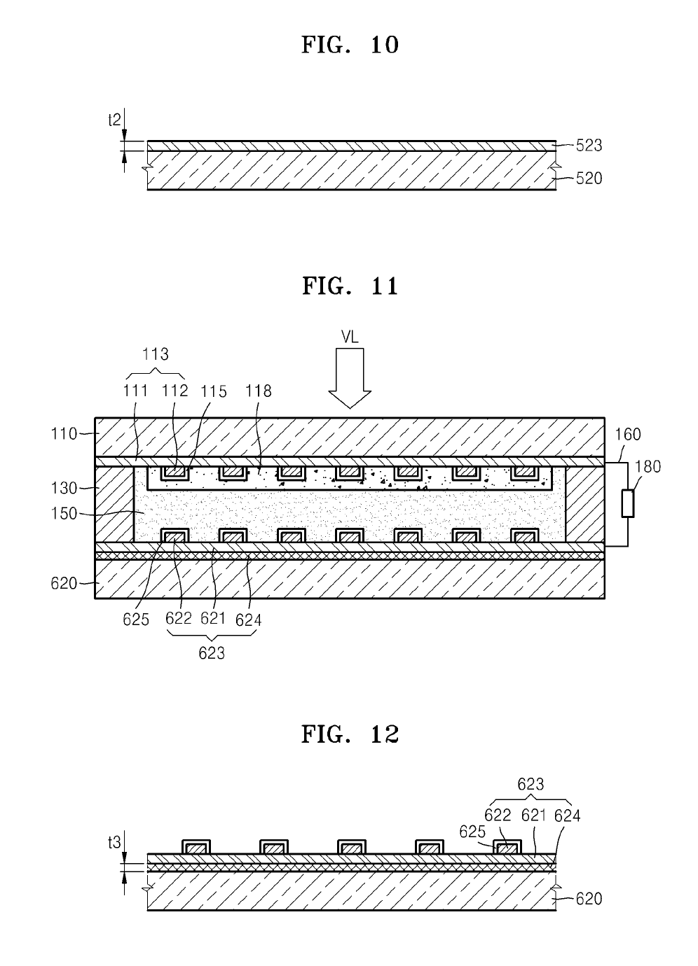

FIG. 11 is a cross-sectional view of a photoelectric conversion device, according to another exemplary embodiment of the present disclosure. FIG. 12 is detailed cross-sectional view of a counter substrate side illustrated in FIG. 11.

Referring to FIGS. 11 and 12, a light-receiving substrate 110, on which a photoelectrode 113 is formed, and a counter substrate 620, on which a counter electrode 623 is formed, are disposed facing each other. An electrolyte layer 150 is filled in between the light-receiving substrate 110 and the counter substrate 620. A semiconductor layer 118 into which a photosensitive dye is absorbed, is formed on the photoelectrode 113. The photoelectrode 113 includes a transparent conductive film 111 and grid electrodes 112 formed on the transparent conductive film 111.

The counter electrode 623, which faces the photoelectrode 113, includes a thin metal layer 624, a catalyst layer 621 formed on the thin metal layer 624, and grid electrodes 622 formed in a mesh pattern on the catalyst layer 621. The thin metal layer 624 is directly formed on one surface of the counter substrate 620. In particular, a TCO layer is not included in the counter electrode 623. Therefore, there is no need for the associated unique film-forming process and a high material costs required to form the TCO layer.

The thin metal layer 624 replaces the TCO layer, so as to supplement the conductivity of the counter electrode 623. For example, the thin metal layer 624 may be formed of a metallic material having an excellent electrical conductivity, such as Au, Ag, or Al. However, since the thin metal layer 624 is formed of an opaque metallic material, the thickness t3 of the thin metal layer 624 may be restricted, such that the metal layer 624 is in the form of a thin film, in order to ensure a certain level of light transmittance.

The catalyst layer 621 is formed on a surface of the thin metal layer 624 that faces the electrolyte layer 150, and operates as a reduction catalyst providing electrons to the electrolyte layer 150. The grid electrodes 622 may be patterned in a mesh shape, and may be formed of a metallic material having an excellent electrical conductivity, such as Au, Ag, or Al. A protective layer 625 may be formed on outer surfaces of the grid electrodes 622.

As described above, according to the one or more of the above exemplary embodiments, as a counter electrode of a non-light receiving side does not include a TCO layer, while equivalently maintaining or improving electric properties of the counter electrode, high material costs and an expensive unique film-forming process required to form the TCO layer are not be required. Thus a photoelectric conversion device may be manufactured at a low cost.

Although a few exemplary embodiments of the present disclosure have been shown and described, it would be appreciated by those skilled in the art that changes may be made in these exemplary embodiments, without departing from the principles and spirit of the disclosure, the scope of which is defined in the claims and their equivalents.

What is claimed is:

1. A photoelectric conversion device comprising:
a light-receiving substrate;
a photoelectrode disposed on the light receiving substrate;
a counter substrate facing the light-receiving substrate;
a counter electrode comprising a catalyst layer disposed directly on the counter substrate;
a semiconductor layer disposed on the photoelectrode, comprising a photosensitive dye absorbed therein; and
an electrolyte layer disposed between the semiconductor layer and the counter electrode.

2. The device of claim 1, further comprising a protective layer disposed on the counter electrode.

3. The device of claim 1, wherein the counter electrode further comprises grid electrodes formed on the catalyst layer.

4. The device of claim 3, wherein the width of the grid electrodes is equal to or less than about 0.1 mm.

5. The device of claim 3, wherein the distance between adjacent ones of the grid electrodes is equal to or less than about 2 mm.

6. The device of claim 3, wherein the distance between adjacent ones of the grid electrodes is equal to or less than about 1 mm.

7. The device of claim 3, wherein the grid electrodes comprise:
bus bars that extend in parallel; and
a connection bar that electrically connects ends of the bus bars.

8. The device of claim 3, wherein the grid electrodes comprise:
main bus bars disposed in a striped pattern;
sub-bus bars that connect adjacent ones of the main bus bars; and
a connection bar that extends across ends of the main bus bars, to transfer electrons from the main bus bars to the outside of the photoelectric conversion device.

9. The device of claim 8, wherein the grid electrodes further comprise protruding bus bars that protrude from the main bus bars, into windows at least partially defined by the main bus bars and the sub-bus bars.

10. The device of claim 1, wherein the catalyst layer is formed by performing a sputtering process for more than about 600 sec.

11. The device of claim 1, wherein the photoelectrode comprises:
a transparent conductive film formed on the light-receiving substrate; and
grid electrodes formed on the transparent conductive film.

12. A photoelectric conversion device comprising:
a light-receiving substrate;
a photoelectrode disposed on the light-receiving substrate;
a counter substrate disposed facing the light-receiving substrate;
a counter electrode comprising a metal layer disposed directly on the counter substrate, and a catalyst layer formed on the metal layer;
a semiconductor layer disposed on the photoelectrode, comprising a photosensitive dye absorbed therein; and
an electrolyte layer disposed between the semiconductor layer and the counter electrode.

13. The device of claim 12, wherein a transparent conductive oxide (TCO) layer is not formed between the counter substrate and the catalyst layer.

14. The device of claim 12, wherein the counter electrode further comprises grid electrodes formed on the catalyst layer.

15. The device of claim 14, wherein the width of the grid electrodes is equal to or less than about 0.1 mm.

16. The device of claim 14, wherein the distance between adjacent ones of the grid electrodes is equal to or less than about 2 mm.

17. The device of claim 14, wherein the distance between adjacent ones of the grid electrodes is equal to or less than 1 mm.

18. The device of claim 14, wherein the grid electrodes comprise:
bus bars that extend in parallel, in a striped pattern; and
a connection bar that extends across ends of the bus bars, to transfer electrons from the bus bars to the outside of the photoelectric conversion device.

19. The device of claim 14, wherein the grid electrodes comprise:
main bus bars that extend in a stripe pattern;
sub-bus bars that connect adjacent ones of the main bus bars; and
a connection bar that extends across ends of the main bus bars, to transfer electrons from the bus bars to the outside the photoelectric conversion device.

20. The device of claim 19, wherein the grid electrodes further comprise protruding bus bars that protrude from the main bus bars, into windows at least partially defined by the main bus bars and the sub-bus bars.

21. The device of claim 12, wherein the catalyst layer is formed by performing a sputtering process for more than about 600 sec.

22. The device of claim 12, wherein the photoelectrode comprises:
a transparent conductive film formed on the light-receiving substrate; and
grid electrodes formed on the transparent conductive film.
